(19) United States
(12) Patent Application Publication
(10) Pub. No.: US 2024/0034912 A1
(43) Pub. Date: Feb. 1, 2024

(54) MICROFIBER ARRAY HAVING ROUGHENED TIPS FOR HANDLING OF SEMICONDUCTOR DEVICES

(71) Applicant: Setex Technologies, Inc., Pittsburgh, PA (US)

(72) Inventors: Paul Samuel Glass, Pittsburgh, PA (US); Metin Sitti, Pittsburgh, PA (US)

(73) Assignee: Setex Technologies, Inc., Pittsburgh, PA (US)

(21) Appl. No.: 18/268,346

(22) PCT Filed: Dec. 22, 2021
(86) PCT No.: PCT/US2021/064935

§ 371 Date: Jun. 20, 2023

Related U.S. Application Data
(60) Provisional application No. 63/128,903, filed on Dec. 22, 2020.

(51) Int. Cl. C09J 7/00; H01L 21/687

(52) U.S. Cl. CPC C09J 7/00; H01L 21/68707; C09J 2301/31

(57) ABSTRACT

A microfiber array comprising a plurality of fibers with roughened tips, where the microfiber array is adapted to provide enhanced grip to the surface of a semiconductor device and other smooth, flat objects. The microfiber array provides friction against movement in the horizontal direction, while providing controllable adhesion to allow for easy separation in the vertical direction.

### CROSS-REFERENCE TO RELATED APPLICATIONS

This application claims the benefit under 35 U.S.C. § 119 of U.S. Provisional Application No. 63/128,903, filed Dec. 22, 2020, which is incorporated herein by reference.

### STATEMENT REGARDING FEDERALLY SPONSORED RESEARCH

Not applicable.

### BACKGROUND OF THE INVENTION

The invention relates generally to microfiber arrays providing enhanced friction to surfaces. More specifically, the invention relates to an array of micro- and nano-scale fiber arrays that have fibers with roughened tips that provide friction characteristics and controllable weak normal adhesion useful in the handling of smooth and flat objects, such as the handling of semiconductor devices during the fabrication process.

Semiconductor manufacturing involves several processing steps. For example, a silicon wafer being fabricated into a die may undergo cleaning, passivation, photolithography, etching, deposition, polishing, grinding, dicing, chip/die packaging, etc. Each of these steps is performed in a dedicated piece of equipment within a larger fabrication environment. Careful handling of the wafers, dies, and other semiconductor devices is required during and between each processing step to reduce/prevent particle contamination, maintain high yields, and reduce the footprint of equipment in the fabrication area. In addition, increasing the speed in which the semiconductor devices are moved from one processing area to another can improve throughput. More specifically, in one typical wafer handling process, a semiconductor wafer will be rapidly accelerated by machinery in contact with the backside of the wafer. The maximum possible rate of acceleration without slippage depends on the friction between the end effector of the machine and the wafer. With greater friction, the device can be accelerated more rapidly, increasing the process throughput, and thus its profitability. While efficiency is critical, wafers must also be able to be released easily, with near zero vertical adhesion between the wafer and end effector pad. If adhesive forces at this interface are too high, there is increased risk of: (1) semiconductor device damage, (2) semiconductor device mis-alignment, and (3) residual contamination from the end effector which reduces the yield of the semiconductor.

Many manufacturers use elastomer pads with or without vacuum clamping on the end effector of the machinery used to move or transfer the semiconductor device. However, elastomer pads can introduce contamination as the soft rubber materials wear, leaving microscopic particles on the semiconductor device. Similarly, vacuum clamping can introduce contamination or damage thin or curved surfaces of some semiconductor devices. They can also be expensive to operate and maintain. Pressure sensitive adhesives are not often used because they can leave residue on the semiconductor device and require increased effort to release from the end effector. Therefore, novel materials which demonstrate high friction with surfaces such as those on a semiconductor wafer or device while minimizing normal adhesion at this interface will overcome the limitations of conventional solutions and have significant commercial value.

### BRIEF SUMMARY

One embodiment of the present invention is a microfiber array having fibers with roughened tips capable of providing a controlled amount of friction when in contact with smooth flat surfaces and patterned surfaces, such as the surface of a silicon wafer while maintaining controllable near zero adhesion at the interface of the roughened fiber tips and the contacting surface. The microfiber array, in one embodiment, comprises a plurality of micro- or nano-scale fibers extending from a surface, where the fibers have an enlarged, shaped tip with a rough surface. The tips make contact with the surface of the wafer or other object and provide a friction force, but little to no adhesion. With controllable low adhesion, a semiconductor device in contact with the microfiber array can be moved rapidly from one manufacturing process to the next, while easily released from the surface in the vertical direction.

### BRIEF DESCRIPTION OF THE SEVERAL VIEWS OF THE DRAWINGS

FIGS. 1-2 are images showing the structure of the microfiber array, according to one embodiment.

FIG. 3 is the microfiber array according to an alternative embodiment.

FIG. 4 is a graph showing the relative performance of a roughened tip fiber.

### DETAILED DESCRIPTION

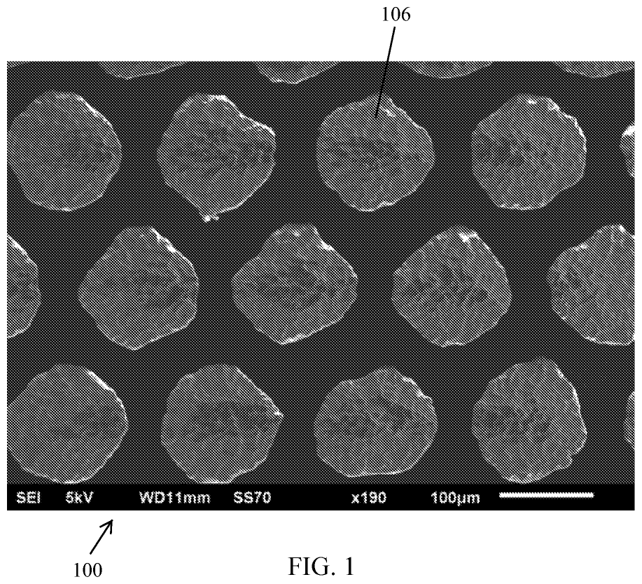

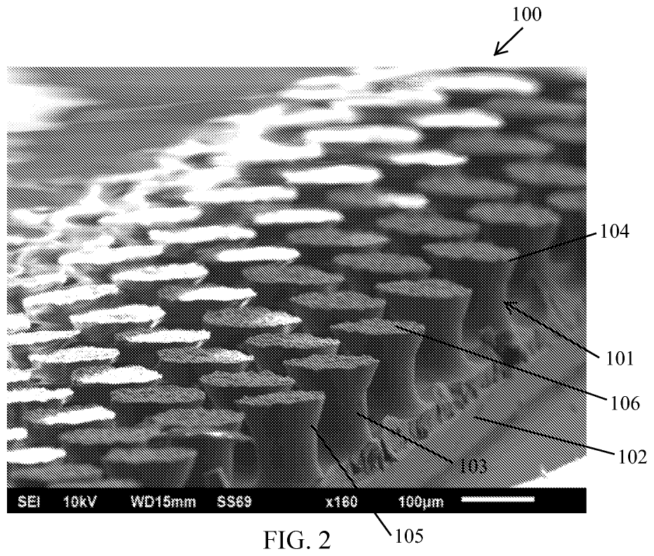

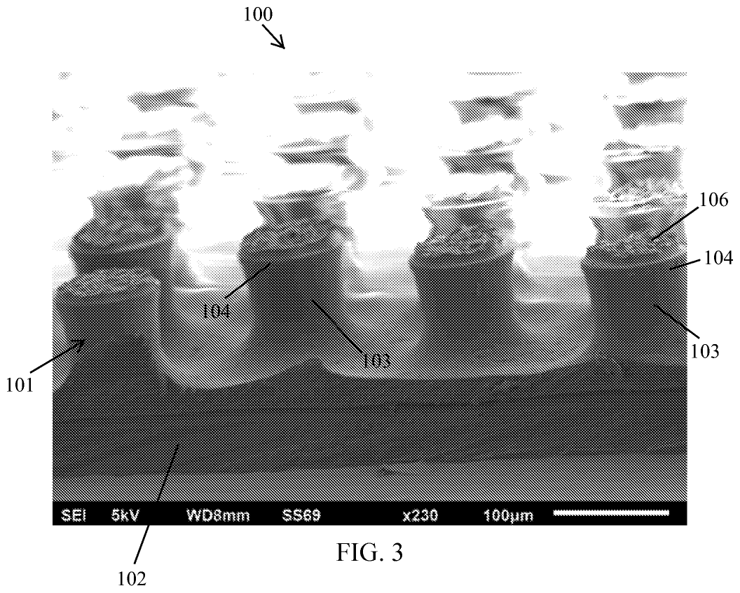

In one example embodiment, as shown in FIGS. 1-2, the microfiber array 100 comprises a plurality of fibers 101 attached to a backing layer, carrier, end effector, or substrate 102. In this embodiment, the fiber 101 attaches to the backing layer, carrier, end effector, or substrate 102 at a substantially perpendicular angle. However, in alternative embodiments, the fiber 101 attachment is non-orthogonal. Each fiber includes stem 103 and an enlarged tip 104 (i.e. the radius of the tip is greater than the radius of the stem); alternatively, some embodiments may have a tip 104 substantially the diameter of the stem 103 (see FIG. 3). In one embodiment, the tip 104 is a mushroom-shaped tip 104 with a flat, roughened surface 106.

The stem 103 and tip 104 are symmetrical about a symmetry axis, such that radius of the stem 103 (up to the point of connection 105 with the tip 104) is constant along the length of the stem 103. However, in alternative embodiments, the radius of the stem 103 can vary along its length, including one embodiment where the radius of the stem 103 near the backing layer 102 is enlarged. The tip 104 can be symmetrical and fixed in a radial direction to enable increased contact with the surface of the semiconductor device, such as a silicon wafer, chip, die, semiconductor package, or other similar device. In one embodiment, the surface of the tip 104 and the cross-section of the stem 103 are circular. In other embodiments, however, an oval or elliptical shape and/or cross-section may be used. The shape of the sides on the underside of the mushroom tip 104 is linear but, alternatively, can be convex or concave with respect to the stem axial direction and tip surface. In the example embodiment shown in FIGS. 1-2, the fibers have a stalk diameter of 100 μm, a tip diameter of ˜130 μm, a height of 140 μm, and a center to center distance between fibers 101 of about 200 μm. In one embodiment, the aspect ratio between the fiber height and the fiber stem diameter is approximately 1:1. In other embodiments, this aspect ratio may range from 0.001:1 to 1000:1. In yet another embodiment, the aspect ratio may range from 0.1-100. These aspect ratio ranges hold for embodiments where the tip diameter is substantially larger than the stem diameter, as well as embodiments where the tip diameter is substantially the diameter of the stem.

In one embodiment, the microfiber array 100 is disposed on the surface of an end effector (i.e. the part of the robotic machinery used to move the semiconductor device). The microfiber array 100 can be formed then adhered to the end effector or, alternatively, molded directly to the surface of the end effector. A wafer can be placed on top of the microfiber array 100 with the weight of the wafer supported by the end effector. While supported by the end effector, the wafer can be moved with the microfiber array 100 providing sufficient friction to prevent the wafer from displacements out of the process specification relative to the end effector. The frictional properties of the microfiber array 100 minimizes contact between the end effector and the semiconductor device. Once transferred to a subsequent location, the wafer can be easily removed from the end effector in the vertical (i.e. normal) direction. Because the microfiber array 100 provides controllable, near-zero adhesion, the release of the device is accurate and repeatable. While this example embodiment discusses handling of semiconductor devices, the array 100 is suitable for handling a variety of objects with smooth and flat (or slightly curved) surfaces that are difficult to grip with conventional tools. Such objects may include optical components, lenses, glass, and sensitive or fragile objects.

The microfiber array 100 is fabricated using a molding process, where a curable polymer is poured into a mold having negative cavities in the shape of the fibers shown in FIGS. 1-2. In one embodiment, the polymer is a Shore 50A polyurethane (BJB 3150). To create the roughened tip surface 106, the microfiber array 100 is molded according to processes known in the art. The microfiber array (with smooth tips at this stage of the process) is then placed onto a surface having a thin film of liquid polymer, which wets the tip surface 106. The wetted tips are then placed into contact with a roughened surface, such as frosted glass, sandpaper, or any similar surface with a consistent roughened surface finish (i.e. uniform roughness over the area of the wetted tips). After a period of time, the microfiber array 100 is cured while still in contact with the roughened surface, allowing the tip surface 106 to retain the roughness of the surface. This microfiber array 100 can then be delaminated from the roughened surface, yielding the array 100 with roughened tips 104. In an alternative fabrication method, a negative cast of the product of the previous manufacturing steps can be produced using casting polymers known in the art, such as silicones. This negative replica can then be molded with a polymer compound to produce an array 100 with roughened tips. Such negative replica surfaces can be integrated with conventional high throughput polymer manufacturing processes such as those described below, but not limited to:
A. Injection molding: Injection over molding, Co-injection molding, Gas assist injection molding, Tandem injection molding, Ram injection molding, Micro-injection molding, Vibration assisted molding, Multiline molding, Counter flow molding, Gas counter flow molding, Melt counter flow molding, Structural foam molding, Injection-compression molding, Oscillatory molding of optical compact disks, Continuous injection molding, Reaction injection molding (Liquid injection molding, Soluble core molding, Insert molding), and Vacuum Molding;
B. Compression molding: Transfer molding, and Insert molding;
C. Thermoforming: Pressure forming, Laminated sheet forming, Twin sheet thermoforming, and Interdigitation;
D. Casting: Encapsulation, Potting, and impregnation;
E. Coating Processes: Spray coating, Powder coatings, Vacuum coatings, Microencapsulation coatings, Electrode position coatings, Floc coatings, and Dip coating;
F. Blow molding: Injection blow molding, Stretch blow molding, and Extrusion blow molding;
F. Vinyl Dispersions: Dip molding, Dip coatings, Slush molding, Spray coatings, Screened inks, and Hot melts; and
G. Composite manufacturing techniques involving molds: Autoclave processing, Bag molding, Hand lay-up, and Matched metal compression.

In one embodiment, the molded fiber array 100 with roughened tips 104 is produced from a perfluorinated elastomer, conventionally used in semiconductor fabrication environments. In other embodiments, the product may be produced from one of the following:

A. Thermosets:
i. Formaldehyde Resins (PF, RF, CF, XF, FF, MF, UF, MUF);
ii. Polyurethanes (PU);
iii. Unsaturated Polyester Resins (UP);
iv. Vinylester Resins (VE), Phenacrylate Resins, Vinylester Urethanes (VU);
v. Epoxy Resins (EP);
vi. Diallyl Phthalate Resins, Allyl Esters (PDAP);
vii. Silicone Resins (Si); and
viii. Rubbers: R-Rubbers (NR, IR, BR, CR, SBR, NBR, NCR, IIR, PNR, SIR, TOR, HNBR), M-Rubbers (EPM, EPDM, AECM, EAM, CSM, CM, ACM, ABM, ANM, FKM, FPM, FFKM), O-Rubbers (CO, ECO, ETER, PO), Q-(Silicone) Rubber (MQ, MPQ, MVQ, PVMQ, MFQ, MVFQ), T-Rubber (TM, ET, TCF), U-Rubbers (AFMU, EU, AU) Text, and Polyphosphazenes (PNF, FZ, PZ)

B. Thermoplastics
i. Polyolefins (PO), Polyolefin Derivates, and Copoplymers: Standard Polyethylene Homo- and Copolymers (PE-LD, PE-HD, PE-HD-HMW, PE-HD-UHMW, PE-LLD); Polyethylene Derivates (PE-X, PE+PSAC); Chlorinated and Chloro-Sulfonated PE (PE-C, CSM); Ethylene Copolymers (ULDPE, EVAC, EVAL, EEAK, EB, EBA, EMA, EAA, E/P, EIM, COC, ECB, ETFE; Polypropylene Homopolymers (PP, H-PP);
ii. Polypropylene Copoplymers and -Derivates, Blends (PP-C, PP-B, EPDM, PP+EPDM);
iii. Polybutene (PB, PIB);
iv. Higher Poly-a-Olefins (PMP, PDCPD);
v. Styrene Polymers: Polystyrene, Homopolymers (PS, PMS); Polystyrene, Copoplymers, Blends; Polystyrene Foams (PS-E, XPS);
vi. Vinyl Polymers: Rigid Polyvinylchloride Homopolymers (PVC-U); Plasticized (Soft) Polyvinylchloride (PVC-P); Polyvinylchloride: Copolymers and Blends; Polyvinylchloride: Pastes, Plastisols, Organosols; Vinyl Polymers, other Homo- and Copolymers (PVDC, PVAC, PVAL, PVME, PVB, PVK, PVP);
vii. Fluoropolymers: FluoroHomopolymers (PTFE, PVDF, PVF, PCTFE); Fluoro Copolymers and Elastomers (ECTFE, ETFE, FEP, TFEP, PFA, PTFEAF, TFEHFPVDF (THV), [FKM, FPM, FFKM]);
viii. Polyacryl- and Methacryl Copolymers;
ix. Polyacrylate, Homo- and Copolymers (PAA, PAN, PMA, ANBA, ANMA);
x. Polymethacrylates, Homo- and Copolymers (PMMA, AMMA, MABS, MBS);
xi. Polymethacrylate, Modifications and Blends (PMMI, PMMA-HI, MMA-EML Copolymers, PMMA+ABS Blends;
xii. Polyoxymethylene, Polyacetal Resins, Polyformaldehyde (POM): Polyoxymethylene Homo- and Copolymers (POM-H, POM-Cop.); Polyoxymethylene, Modifications and Blends (POM+PUR);
xiii. Polyamides (PA): Polyamide Homopolymers (AB and AA/BB Polymers) (PA6, 11, 12, 46, 66, 69, 610, 612, PA 7, 8, 9, 1313, 613); Polyamide Copolymers, PA 66/6, PA 6/12, PA 66/6/610 Blends (PA+: ABS, EPDM, EVA, PPS, PPE, Rubber); Polyamides, Special Polymers (PA NDT/INDT [PA 6-3-t], PAPACM 12, PA 6-I, PA MXD6 [PARA], PA 6-T, PA PDA-T, PA 6-6-T, PA 6-G, PA 12-G, TPA-EE); Cast Polyamides (PA 6-C, PA 12-C); Polyamide for Reaction Injection Molding (PA-RIM); Aromatic Polyamides, Aramides (PMPI, PPTA);
xiv. Aromatic (Saturated) Polyesters: Polycarbonate (PC); Polyesters of Therephthalic Acids, Blends, Block Copolymers; Polyesters of Aromatic Diols and Carboxylic Acids (PAR, PBN, PEN);
xv. Aromatic Polysulfides and Polysulfones (PPS, PSU, PES, PPSU, PSU+ABS): Polyphenylene Sulfide (PPS); Polyarylsulfone (PSU, PSU+ABS, PES, PPSU);
xvi. Aromatic Polyether, Polyphenylene Ether, and Blends (PPE): Polyphenylene Ether (PPE); Polyphenylene Ether Blends;
xvii. Aliphatic Polyester (Polyglycols) (PEOX, PPOX, PTHF);
xviii. Aromatic Polyimide (PI): Thermosetting Polyimide (PI, PBMI, PBI, PBO, and others); Thermoplastic Polyimides (PAI, PEI, PISO, PMI, PMMI, PESI, PARI);
xix. Liquid Crystalline Polymers (LCP);
xx. Ladder Polymers: Two-Dimensional Polyaromates and -Heterocyclenes: Linear Polyarylenes; Poly-p-Xylylenes (Parylenes); Poly-p-Hydroxybenzoate (Ekonol); Polyimidazopyrrolone, Pyrone; Polycyclone;
xxi. Biopolymers, Naturally Occurring Polymers and Derivates: Cellulose- and Starch Derivates (CA, CTA, CAP, CAB, CN, EC, MC, CMC, CH, VF, PSAC); 2 Casein Polymers, Casein Formaldehyde, Artificial Horn (CS, CSF); Polylactide, Polylactic Acid (PLA); Polytriglyceride Resins (PTP®); xix. Photodegradable, Biodegradable, and Water Soluble Polymers;
xxii. Conductive/Luminescent Polymers;
xxiii. Aliphatic Polyketones (PK);
xxiv. Polymer Ceramics, Polysilicooxoaluminate (PSIOA);
xxv. Thermoplastic Elastomers (TPE): Copolyamides (TPA), Copolyester (TPC), Polyolefin Elastomers (TPO), Polystyrene Thermoplastic Elastomers (TPS), Polyurethane Elastomers (TPU), Polyolefin Blends with Crosslinked Rubber (TPV), and Other TPE, TPZ; and
xxvi. Other materials known to those familiar with the art.

The roughened surface can include plastic, metal, glass, or a natural surface. Moreover, the surface can be treated to produce an appropriate surface texture. Treatments can include machining, sawing, milling, cutting, planing, additive manufacturing processes, boring, broaching, turning, grinding, sanding, sand-blasting, sand-casting, perm mold casting, investment casting, hot rolling, forging, extruding, cold rolling, flame cutting, chemical milling, EDM, and plasma etching. After placed in contact with the roughened surface, the polymer is cured, with the tips 104 retaining the rough texture of the roughened surface. In one example embodiment, the roughened surface 106 of the tips 104 can have an Ra of 1-20 μm, where Ra is the profile roughness (or roughness average) of the surface 106. However, a person having skill in the art will appreciate that the surface roughness can be varied to alter the coefficient of friction of the microfiber array 100. In addition to surface roughness, the tip diameter, stem diameter, stem length, fiber spacing, tip height, and other parameters can be altered to adjust the coefficient of friction and adhesion of the microfiber array 100.

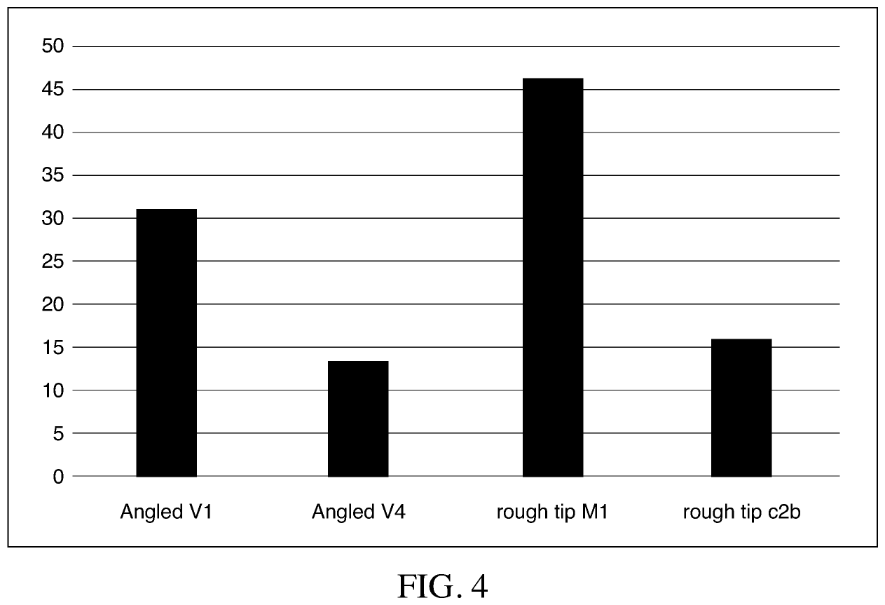

FIG. 4 shows the ratio of friction to adhesion for various materials, with the ‘rough tip M1’ line corresponding to the microfiber array 100 shown in FIGS. 1-2. As shown in FIG. 4, the roughened tip fiber array 100 of the present invention offers a friction to adhesion ratio over ˜45, whereas typical rubber pads have a ratio of roughly 1:1 or less. The ratio of the microfiber array 100 is a significant improvement over traditional materials and is capable of altering the way semiconductor devices are handled during the fabrication process.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilized for realizing the invention in diverse forms thereof. In particular, one or more features in any of the embodiments described herein may be combined with one or more features from any other embodiments described herein.

Protection may also be sought for any features disclosed in any one or more published documents referred to and/or incorporated by reference in combination with the present disclosure.

What is claimed is:

1. A microfiber array for use in handling an object comprising:
a dry adhesive microfiber array having a plurality of fibers, each fiber of the plurality of fibers terminating in an enlarged tip,
wherein each tip has a roughened surface; and
wherein the roughened surface provides a controlled coefficient of friction.

2. The microfiber array of claim 1, wherein the plurality of tips provides a controlled normal adhesion.

3. The microfiber array of claim 2, wherein the controlled normal adhesion is near zero.

4. The microfiber array of claim 2, wherein the array has a friction to adhesion ratio of at least 45.

5. The microfiber array of claim 1, wherein the roughened surface has a roughness average of 1-20 μm.

6. The microfiber array of claim 1, wherein the object comprises a semiconductor device.

7. The microfiber array of claim 1, wherein a roughness average of the roughened surface is controlled to affect a friction to adhesion ratio.

8. A microfiber array for use in handling an object comprising:
a dry adhesive microfiber array having a plurality of fibers each having a tip,
wherein each tip has a roughened surface; and
wherein the roughened surface provides a controlled coefficient of friction.

9. The microfiber array of claim 8, wherein the tips provide a controlled normal adhesion.

10. The microfiber array of claim 9, wherein the controlled normal adhesion is near zero.

11. The microfiber array of claim 9, wherein the array has a friction to adhesion ratio of at least 45.

12. The microfiber array of claim 8, wherein the roughened surface has a roughness average of 1-20 μm.

13. The microfiber array of claim 8, wherein the object comprises a semiconductor device.

14. The microfiber array of claim 8, wherein a roughness average of the roughened surface is controlled to affect a friction to adhesion ratio.

15. A method of fabricating a microfiber array for use in handling semiconductor devices comprising:
forming the microfiber array from a curable polymer using a mold;
wetting the tips of the cured microfiber array with a second curable polymer;
placing the microfiber array with wetted tips on a roughened surface, wherein the wetted tips of the microfiber array are in contact with the roughened surface; and
curing the second curable polymer.

16. A method of claim 15, further comprising;
molding the cured microfiber array with roughened tips with a casting material to form a negative replica of the microfiber array with roughened tips; and
molding the negative replica with the curable polymer to form an additional microfiber array.

17. The method of claim 16, wherein molding the negative array is accomplished through compression molding.

18. The method of claim 16, wherein molding the negative array is accomplished through injection molding.

19. The method of claim 15, wherein the roughened surface is frosted glass.
